(19) United States
(12) Patent Application Publication
(10) Pub. No.: US 2026/0359523 A1
(43) Pub. Date: Nov. 12, 2026

(54) SYSTEMS AND METHODS FOR COMPUTER NETWORK MODEL MERGING

(71) Applicant: Capital One Services, LLC, McLean, VA (US)

(72) Inventors: Genta Winata, New York, NY (US); Anirban Das, San Mateo, CA (US); Chinmaya Andukuri, McLean, VA (US); Supriyo Chakraborty, McLean, VA (US); Sambit Sahu, Hopewell Junction, NY (US); Shixiong Zhang, Redmond, WA (US); Ayushman Singh, McLean, VA (US); Mingyang Zhou, McLean, VA (US); Chia-Hsuan Lee, McLean, VA (US); Berkcan Kapusuzoglu, McLean, VA (US)

(73) Assignee: Capital One Services, LLC, McLean, VA (US)

(21) Appl. No.: 19/212,546

(22) Filed: May 19, 2025

Related U.S. Application Data
(60) Provisional application No. 63/802,478, filed on May 8, 2025.

(51) Int. Cl. G06F 30/27

(52) U.S. Cl. CPC G06F 30/27

(57) ABSTRACT

The system may generate a first feature input based on a first computer network model and a second computer network model, wherein the first computer network model is calibrated for a first networking task and comprises a first parameter, and wherein the second computer network model is calibrated for a second networking task and comprises a second parameter. The system may input the first feature input into a third computer network model to determine a first weight for the first parameter and a second weight for the second parameter, wherein the third computer network model is trained to determine consolidated models by merging inputted computer network models by modifying weights attributed to individual parameters.

### CROSS-REFERENCE TO RELATED APPLICATIONS

This application claims the benefit of priority of U.S. Provisional Application No. 63/802,478, filed May 8, 2025. The content of the foregoing application is incorporated herein in its entirety by reference.

### BACKGROUND

Retraining computer network models poses significant technical challenges due to the complexity and dynamic nature of network environments. First, network conditions—such as traffic patterns, node availability, and protocol efficiencies—can change rapidly over time, making it difficult for a static retrained model to generalize well without frequent updates. This leads to issues of data drift and concept drift, where previously collected training data may no longer accurately represent the current operating environment, resulting in degraded model performance. Additionally, gathering high-quality, real-time network data for retraining can be resource-intensive, requiring careful handling of sensitive or proprietary information to maintain privacy and security. Scalability also becomes a concern, as retraining large models on massive and constantly evolving network datasets demands substantial computational resources and efficient data management strategies. Moreover, retraining carries the risk of introducing instability into critical systems; if the updated model underperforms or behaves unpredictably, it could disrupt essential network operations. Version control and rollback mechanisms must be carefully implemented to mitigate such risks. Finally, coordinating retraining across distributed systems or hybrid cloud environments adds additional layers of complexity, particularly around synchronizing model updates, minimizing downtime, and ensuring consistent deployment. Together, these factors make retraining computer network models a technically demanding process requiring robust infrastructure, rigorous validation, and adaptive learning strategies.

### SUMMARY

Systems and methods are described herein for novel uses and/or improvements to merging computer network models. For example, merging existing models can mitigate the technical challenges of retraining computer network models by allowing systems to leverage the strengths of previously trained models without the need for complete retraining from scratch. Instead of building a new model solely from fresh data, a system can combine the knowledge and decision-making capabilities of multiple existing models, each trained on different datasets or specialized for particular conditions. This approach addresses data drift and concept drift by incorporating models that already handle diverse scenarios, thus broadening overall coverage without requiring constant, resource-intensive retraining cycles. Model merging can also reduce computational costs, as it avoids the need for full reprocessing of historical data, allowing incremental updates or specialized improvements to be layered onto existing architectures. Additionally, merging helps maintain system stability, since the models being combined have already been validated individually, reducing the risk of catastrophic performance degradation when adapting to new environments. Version control becomes simpler as well, because changes can be modular—specific models can be updated or swapped without disrupting the entire system. Finally, in distributed or hybrid settings, merging localized models into a federated or ensemble structure enables flexible adaptation to regional network behaviors without requiring a unified, large-scale retraining effort. Altogether, model merging offers a scalable, efficient, and resilient strategy for evolving network intelligence in the face of continual change.

While merging models offers significant advantages, it also introduces novel technical challenges. One major challenge is model compatibility, as different models may have been trained with varying architectures, input formats, feature spaces, or underlying assumptions, making direct integration nontrivial. Aligning these discrepancies often requires complex preprocessing, feature mapping, or even intermediate translation layers to harmonize the models' outputs. Performance degradation is another risk; when models are merged without careful calibration, conflicts in decision logic or redundancy in predictions can lead to reduced accuracy, inefficiency, or unstable behaviors, especially in sensitive computer network environments.

To overcome these novel technical challenges while still obtaining the benefits of merging models, the systems and methods merge models by adjusting parameter-specific node weights. For example, the system may merge models by adjusting parameter-specific node weights through a gradient-free approach that leverages Gaussian Optimization to identify an optimal combination of model parameters. Unlike traditional retraining methods that require backpropagation and iterative weight updates, the system operates without needing gradient information, making it highly efficient and adaptable. In such cases, the system may begin by taking target task data, which is used purely for validation purposes, allowing it to optimize the merging process specifically for a given task or domain without altering the underlying training structures of the original models. By adjusting node-specific weights through Gaussian Optimization, the system explores the parameter space intelligently, balancing contributions from the different models to maximize performance on the target task. This method offers substantial flexibility, as it seamlessly accommodates a variety of merging strategies and can be easily integrated with other existing approaches to further boost performance. Importantly, the system's merging process is agnostic to the types of models involved—whether they are supervised fine-tuned (SFT) models, preference-tuned models, or even a heterogeneous mixture of both—thus allowing broad applicability across diverse modeling scenarios. This orthogonal merging strategy introduces a novel, scalable way to build customized, high-performance models without the computational burden and complexity traditionally associated with retraining or fine-tuning, making it an ideal solution for rapidly adapting models to evolving tasks and domains.

In some aspects, systems and methods for merging computer network models based on parameter-specific node weights are described. For example, the system may generate a first feature input based on a first computer network model and a second computer network model, wherein the first computer network model is calibrated for a first networking task and comprises a first parameter, and wherein the second computer network model is calibrated for a second networking task and comprises a second parameter. The system may input the first feature input into a third computer network model to determine a first weight for the first parameter and a second weight for the second parameter, wherein the third computer network model is trained to determine consolidated models by merging inputted computer network models by modifying weights attributed to individual parameters. The system may generate a first merged computer network model by applying the first weight to the first parameter and the second weight to the second parameter when processing inputs through the first computer network model and the second computer network model, respectively. The system may input a first input for the first networking task and a second input for the second networking task into the merged computer network model to generate a first output for the first networking task and a second output for the second networking task. The system may generate for display, in a user interface, a recommendation based on the first output and the second output.

Various other aspects, features, and advantages of the invention will be apparent through the detailed description of the invention and the drawings attached hereto. It is also to be understood that both the foregoing general description and the following detailed description are examples and are not restrictive of the scope of the invention. As used in the specification and in the claims, the singular forms of “a,” “an,” and “the” include plural referents unless the context clearly dictates otherwise. In addition, as used in the specification and the claims, the term “or” means “and/or” unless the context clearly dictates otherwise. Additionally, as used in the specification, “a portion” refers to a part of, or the entirety of (i.e., the entire portion), a given item (e.g., data) unless the context clearly dictates otherwise.

### BRIEF DESCRIPTION OF THE DRAWINGS

FIG. 1 shows an illustrative diagram for merging models, in accordance with one or more embodiments.

FIG. 2 shows an illustrative diagram for determining a weight for a parameter in order to merge models, in accordance with one or more embodiments.

FIG. 3 shows illustrative components for a system used to merge models, in accordance with one or more embodiments.

FIG. 4 shows a flowchart of the steps involved in merging computer network models based on parameter-specific node weights, in accordance with one or more embodiments.

FIG. 5 shows a flowchart of the steps involved in merging another model to an existing merged model, in accordance with one or more embodiments.

### DETAILED DESCRIPTION OF THE DRAWINGS

In the following description, for the purposes of explanation, numerous specific details are set forth in order to provide a thorough understanding of the embodiments of the invention. It will be appreciated, however, by those having skill in the art that the embodiments of the invention may be practiced without these specific details or with an equivalent arrangement. In other cases, well-known structures and devices are shown in block diagram form in order to avoid unnecessarily obscuring the embodiments of the invention.

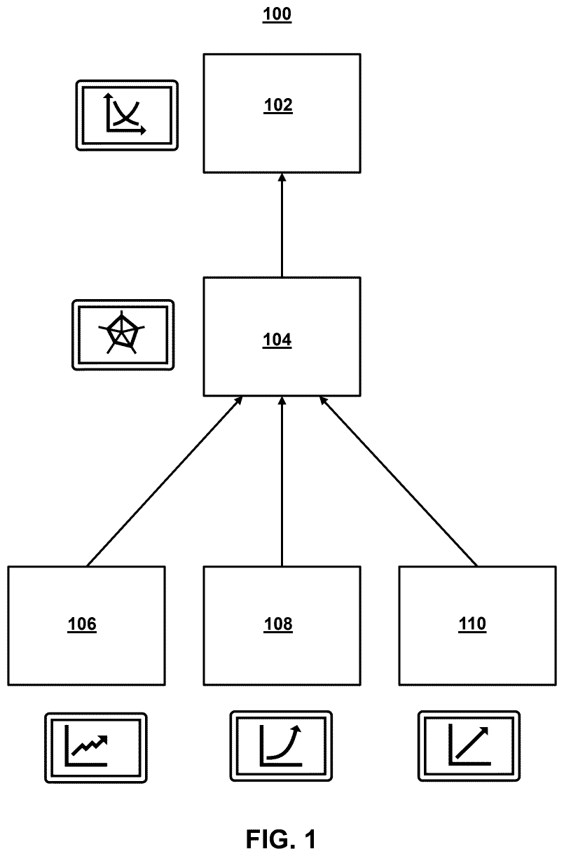

FIG. 1 shows an illustrative diagram for merging models, in accordance with one or more embodiments. System 100, represents a model merging framework that integrates a plurality of fine-tuned models—specifically, fine-tuned model 106, fine-tuned model 108, and fine-tuned model 110—into a single merged model (e.g., merged model 102) through a central merging function 104. For example, the system may be designed to combine these specialized models (e.g., neural network models) without requiring further gradient-based training, instead employing a gradient-free optimization technique, such as Gaussian Optimization, to identify an effective combination of model parameters. This optimization process is guided by performance on target task data, which acts as a validation set to ensure that the merged model is fine-tuned for a specific task or domain.

Merging function 104 may evaluate parameter combinations across the individual models and synthesize them into a unified representation that balances the strengths of each component model. This approach allows for domain-specific customization and task-specific performance tuning without the computational cost of retraining the models from scratch. Moreover, system 100 may be designed to be orthogonal to existing model training and assembling methods, meaning it can be layered on top of or integrated with other techniques to further enhance performance. Its modular structure and gradient-free optimization strategy make it both flexible and efficient, supporting the seamless creation of highly specialized, merged models tailored to varied application needs.

As described herein, a parameter is a numerical value within a machine learning model that is learned during the training process and is essential for the model's ability to make predictions or decisions. In neural networks, parameters typically refer to the weights and biases associated with the connections between neurons in different layers. These weights determine the strength and direction of the influence one neuron has on another, while biases help shift the activation of neurons to improve the model's flexibility. As the model is trained on data samples, it adjusts these parameters to minimize the difference between its predictions and the actual outcomes, thereby learning patterns and relationships in the data. Parameters are distinct from hyperparameters, which are predefined settings (like learning rate or number of layers) that guide the training process but are not learned from the data. The final set of parameters in a trained model encapsulates all the knowledge the model has extracted from the training data, enabling it to generalize and perform tasks such as classification, prediction, or decision-making on new inputs.

As described herein, a merged model may be a unified machine learning model that is created by combining multiple individual models—typically fine-tuned models—into a single composite model. The purpose of merging is to aggregate the learned knowledge, capabilities, or strengths of each individual model while eliminating the need to retrain from scratch. This is often achieved through techniques such as parameter averaging, weighted blending, or more sophisticated optimization strategies like gradient-free methods (e.g., Gaussian Optimization) that determine the best way to integrate the parameters or outputs of the original models. The merged model is designed to perform well on a specific task or domain by leveraging the diverse specializations of the contributing models.

In contrast, individual models are typically trained separately, each on a specific dataset or task, and possess isolated sets of learned weights and behaviors. While an individual model may perform well on the task it was fine-tuned for, it may lack generalization across different domains or fail to incorporate complementary strengths from other models. A merged model differs in that it synthesizes these multiple perspectives, potentially improving robustness, accuracy, and adaptability without requiring retraining. It serves as an efficient and flexible solution for tailoring performance to specific goals while conserving computational resources.

For example, a merged model may differ fundamentally from individual models in both how it is constructed and how it learns. Individual models are each trained independently on specific datasets, meaning their parameters are adjusted through gradient-based learning methods, such as backpropagation, to optimize performance on the particular data samples they are exposed to. Each model becomes specialized based on its unique training data, leading to variations in behavior, representation, and generalization ability. In contrast, a merged model is not trained in the traditional sense; it is created by combining the already-trained parameters of multiple individual models without performing additional learning on new data. This process avoids gradient-based optimization and instead relies on parameter merging techniques—such as linear interpolation or optimization strategies like Gaussian Optimization—to integrate the strengths of the original models. The merged model, therefore, is a synthesis of pre-learned knowledge, not a result of training on individual data samples. This enables the merged model to benefit from the diverse capabilities of its components while avoiding the computational cost and complexity of retraining. As a result, it offers a flexible and efficient solution for task adaptation and performance enhancement across domains.

Data samples are individual units of information drawn from a dataset and are used to train machine learning models for specific tasks. Each sample typically consists of input features—such as text, images, numerical values, or sensor readings—and corresponding labels or outcomes, depending on whether the task is supervised or unsupervised. During training, a model processes these data samples in batches and uses them to learn patterns, relationships, or representations that enable it to make predictions or perform classifications. In supervised learning, for example, the model compares its predicted output with the actual label from each data sample and adjusts its internal parameters (weights) through backpropagation to minimize the prediction error. This iterative process allows the model to generalize from the training samples and perform the target task—such as language translation, image recognition, or sentiment analysis—on new, unseen data. The quality, diversity, and quantity of data samples play a critical role in determining the model's accuracy, robustness, and generalizability. Thus, data samples are the foundational building blocks that shape a model's learning and task-specific performance.

As one example, to create a merged model capable of determining both credit fraud and credit default, two individually trained models—one specialized in detecting fraudulent credit transactions and the other in predicting credit default risk—would first be developed using separate, task-specific datasets. Each model would learn different patterns: the fraud detection model would focus on anomalies, transaction behavior, and red flags typically associated with unauthorized activity, while the default prediction model would learn patterns related to creditworthiness, such as payment history, credit utilization, and financial stability. Rather than retraining a new model from scratch, a merging function would combine the parameters or outputs of these two trained models into a single, unified model. This could be accomplished using gradient-free methods such as Gaussian Optimization, which intelligently weights and blends the models' parameters to optimize performance on a validation dataset that includes both fraud and default signals.

To generate a merged model from two individual models—such as one trained for credit fraud detection and the other for credit default prediction—the system may assign weights to the parameters of each model to balance their influence in the merged output. Each model consists of a set of learned parameters (e.g., weights and biases in neural networks) that capture task-specific patterns from their respective training data. During the merging process, instead of retraining, the system applies a weighted averaging technique or a more sophisticated optimization strategy, such as Gaussian Optimization, to blend these parameters. The weights determine how much influence each model's parameters have on the final merged model. For example, if the target task requires a stronger emphasis on detecting fraud, the parameters from the fraud detection model may be given higher weights, while still incorporating useful features from the default prediction model. The system may also use a validation dataset containing examples relevant to both tasks to fine-tune the weighting scheme, selecting parameter combinations that maximize performance across both objectives. By strategically weighting and combining these parameters, the merged model can retain the specialized strengths of each source model while achieving a balanced, multifunctional capability suited to both detecting fraud and predicting credit default.

The resulting merged model is more effective than each model individually because it encapsulates the specialized knowledge of both models and can simultaneously assess different aspects of credit risk within a single inference process. It avoids the need to run two separate models, reducing computational cost and latency. Furthermore, the merged model can leverage overlapping patterns or shared features—such as unusual spending behavior that might signal both fraud and default risk—enabling more holistic decision-making. This integrative approach not only improves operational efficiency but can also enhance predictive accuracy and consistency by unifying insights from both domains.

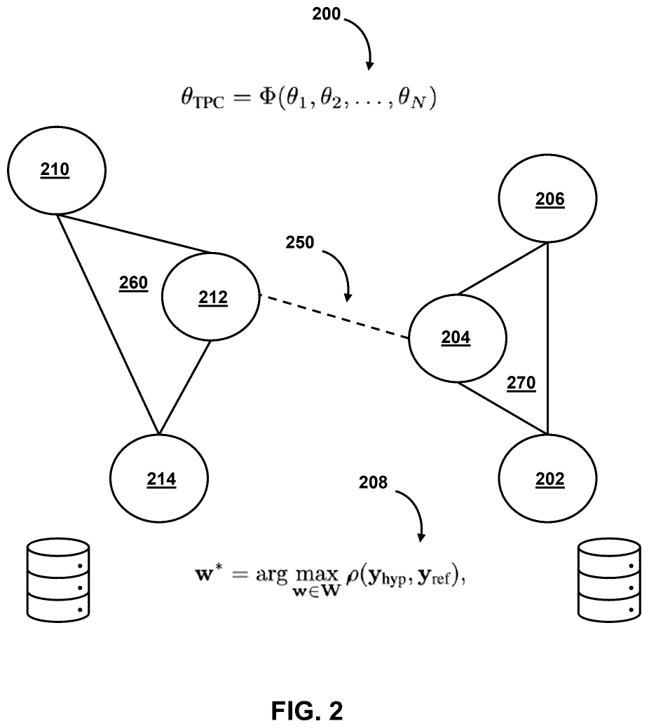

FIG. 2 shows an illustrative diagram for determining a weight for a parameter in order to merge models, in accordance with one or more embodiments. For example, merging models based on parameter contribution and/or weighting is agnostic to the group of models being merged—whether they are supervised fine-tuned (SFT) models, preference-tuned models, or a mix—because the merging process focuses on the structure and values of the learned parameters themselves rather than the specific training objectives or methodologies used to obtain them. Regardless of how the models were fine-tuned, they ultimately consist of the same underlying architecture and parameter space, making their weights directly comparable and combinable. This agnosticism allows the merging function to evaluate and blend parameters purely based on their utility or contribution to the target task, using optimization techniques (such as Gaussian Optimization) to find the best-performing combination. The benefit of this approach is its flexibility and scalability: it enables the integration of models trained for different goals or with different data sources without requiring retraining or alignment of training procedures. This means that developers can leverage diverse model specializations—such as factual grounding from an SFT model and human-aligned reasoning from a preference-tuned model—into a single merged model that inherits strengths from each. As a result, this strategy accelerates model development, reduces resource demands, and promotes modularity in building high-performing, task-specific systems.

FIG. 2 shows model 260 and model 270 being merged based on parameter weighting. For example, using equation 200, which is a mapping function, the system determines the parameter contribution of each model in the merging process to define a task preference calibration. For example, FIG. 2 illustrates a system for merging two computer network models—model 260 and model 270—through parameter weighting to create a task-preference-calibrated model. The merging process is guided by a mapping function represented by equation 200, which calculates the merged parameter set θ_{TPC}=Φ(θ₁,θ₂, . . . , θ_{N}). This function evaluates the contributions of parameters from both models to define a unified representation optimized for specific task requirements.

Model 260 comprises a first node-mapping that includes nodes 210, 212, and 214. This model is calibrated for a first networking task, with node 212 representing a key component that contains a first parameter critical to the model's performance. Similarly, model 270 consists of a second node-mapping including nodes 202, 204, and 206. It is tuned for a second, distinct networking task, where node 204 features a second parameter relevant to that task.

To merge these models effectively, the system introduces a weight—such as weight 250—that determines the influence of parameters from each model in the merged configuration. This weight can be optimized using a performance-based criterion, such as the objective function shown in equation 208, where the goal is to maximize the similarity or alignment ρ(y_{hyp}, y_{ref}) between the hypothesis output and reference data. The merged model thus integrates knowledge from both original models, leveraging task-specific parameter strengths to form a more adaptable and effective solution across domains. This technique enables efficient reuse of specialized models and supports the creation of a generalized model tailored to broader or more complex tasks.

For example, equation 200 defines how the system generates a set of merged parameters, denoted as θ_{TPC}, which stands for Task Preference Calibrated parameters. This set is computed using a merging or mapping function Φ, applied over multiple sets of parameters from the source models: θ_{TPC}=Φ(θ₁,θ₂, . . . , θ_{N}) represents the full set of learned parameters—such as weights and biases—from an individual model that has been trained on a specific task or dataset. The merging function Φ may take various forms depending on the approach being used. It could be a weighted averaging function, where each model's parameters are scaled by a corresponding weight and then combined; a Gaussian optimization process that uses a gradient-free method to explore combinations of parameters that yield optimal performance; or another technique like voting schemes or selective freezing, where only selected parameters are carried forward into the final model. The result, θ_{TPC}, is a new set of parameters designed to blend the knowledge encoded in all contributing models into a unified structure optimized for performance on a new, possibly multi-domain task.

The system may receive a first node-mapping (e.g., featuring node 210, node 212, and node 214) for a first computer network model (e.g., model 260), wherein the first computer network model is calibrated for a first networking task, and wherein the first node-mapping comprises a first node (e.g., node 212) with a first parameter. The system may also receive a second node-mapping (e.g., featuring node 202, node 204, and node 206) for a second computer network model (e.g., model 270), wherein the second computer network model is calibrated for a second networking task, and wherein the second node-mapping comprises a second node (e.g., node 204) with a second parameter. To merge the models, the system may adjust a weight (e.g., weight 250) for one or more parameters.

For example, in this context, a calibrated model means the optimal merged model. The system then maximizes a metric with validation data to find the optimum weights using equation 208. For example, equation 208 quantifies the alignment between the model's outputs and gold labels from a set of tasks. For this optimization, the system may utilize Bayesian Optimization (BO) to construct a posterior distribution of functions, commonly modeled as a Gaussian Process (GP), to represent the function that is being optimized. As more observations are gathered, this posterior distribution becomes increasingly accurate, enabling the algorithm to discern which regions of the parameter space warrant exploration and which can be disregarded. BO is especially adept at predicting unknown functions from observed data, making it a powerful tool for optimizing complex and expensive-to-evaluate functions, such as the correlation between evaluation metric scores and human assessment scores.

Equation 208 further elaborates how the system determines the optimal weights to use in the merging process. This is formulated as an optimization problem, where the goal is to find the best set of weights, denoted w* within a defined weight space W, that maximizes a performance metric. The metric, represented as ρ(y_{hyp}, y_{ref}), evaluates how closely the model's output (the hypothesis y_{hyp} matches the desired reference output y_{ref}. This similarity function ρ could be any appropriate measure depending on the application domain, such as accuracy, BLEU or ROUGE for natural language processing, F1-score, mean squared error (MSE), or other task-specific metrics. The weight vector w influences how much each original model contributes to the merged output, and W defines the allowable configurations—often constrained to ensure non-negative values that sum to one. By solving this optimization, the system identifies w*, the optimal configuration for merging the model parameters.

In the context of the diagram, the system is shown merging two computer network models—model 260 and model 270—each with distinct node-mappings. Model 260 includes nodes 210, 212, and 214 and is calibrated for a first networking task, with node 212 containing a parameter of interest. Model 270 includes nodes 202, 204, and 206, with node 204 featuring a different parameter used in a second networking task. The merging operation is guided by weight 250, which reflects the contribution of the parameters from each model in the merged output. Through the use of the merging function Φ and the optimization procedure (Equation 208), the system creates a new set of parameters θ_{TPC} that intelligently combines the knowledge of both models. This approach is parameter-based and does not require further training, allowing for efficient integration of diverse models and the generation of a task-preferred merged model that benefits from the strengths of each individual contributor.

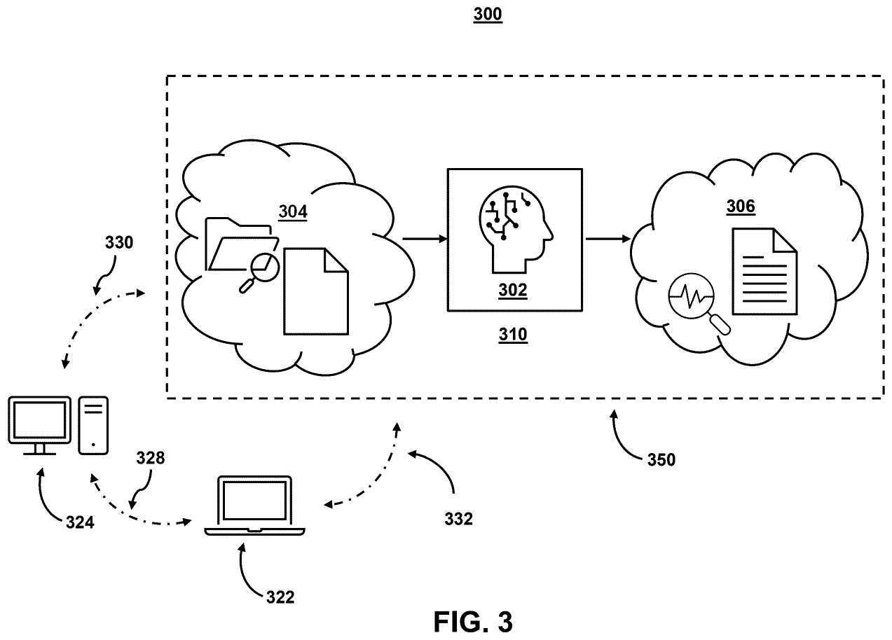

FIG. 3 shows illustrative components for a system used to merge models, in accordance with one or more embodiments. For example, FIG. 3 may show illustrative components for merging computer network models based on parameter-specific node weights. As shown in FIG. 3, system 300 may include mobile device 322 and user terminal 324. While shown as a smartphone and personal computer, respectively, in FIG. 3, it should be noted that mobile device 322 and user terminal 324 may be any computing device, including, but not limited to, a laptop computer, a tablet computer, a handheld computer, and other computer equipment (e.g., a server), including “smart,” wireless, wearable, and/or mobile devices. FIG. 3 also includes cloud components 310. Cloud components 310 may alternatively be any computing device as described above, and may include any type of mobile terminal, fixed terminal, or other device. For example, cloud components 310 may be implemented as a cloud computing system, and may feature one or more component devices. It should also be noted that system 300 is not limited to three devices. Users may, for instance, utilize one or more devices to interact with one another, one or more servers, or other components of system 300. It should be noted that, while one or more operations are described herein as being performed by particular components of system 300, these operations may, in some embodiments, be performed by other components of system 300. As an example, while one or more operations are described herein as being performed by components of mobile device 322, these operations may, in some embodiments, be performed by components of cloud components 310. In some embodiments, the various computers and systems described herein may include one or more computing devices that are programmed to perform the described functions. Additionally, or alternatively, multiple users may interact with system 300 and/or one or more components of system 300. For example, in one embodiment, a first user and a second user may interact with system 300 using two different components.

With respect to the components of mobile device 322, user terminal 324, and cloud components 310, each of these devices may receive content and data via input/output (hereinafter “I/O”) paths. Each of these devices may also include processors and/or control circuitry to send and receive commands, requests, and other suitable data using the I/O paths. The control circuitry may comprise any suitable processing, storage, and/or input/output circuitry. Each of these devices may also include a user input interface and/or user output interface (e.g., a display) for use in receiving and displaying data. For example, as shown in FIG. 3, both mobile device 322 and user terminal 324 include a display upon which to display data (e.g., conversational response, queries, and/or notifications).

Additionally, as mobile device 322 and user terminal 324 are shown as touchscreen smartphones, these displays also act as user input interfaces. It should be noted that in some embodiments, the devices may have neither user input interfaces nor displays, and may instead receive and display content using another device (e.g., a dedicated display device such as a computer screen, and/or a dedicated input device such as a remote control, mouse, voice input, etc.). Additionally, the devices in system 300 may run an application (or another suitable program). The application may cause the processors and/or control circuitry to perform operations related to generating dynamic conversational replies, queries, and/or notifications.

Each of these devices may also include electronic storages. The electronic storages may include non-transitory storage media that electronically stores information. The electronic storage media of the electronic storages may include one or both of (i) system storage that is provided integrally (e.g., substantially non-removable) with servers or client devices, or (ii) removable storage that is removably connectable to the servers or client devices via, for example, a port (e.g., a USB port, a FireWire port, etc.) or a drive (e.g., a disk drive, etc.). The electronic storages may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. The electronic storages may include one or more virtual storage resources (e.g., cloud storage, a virtual private network, and/or other virtual storage resources). The electronic storages may store software algorithms, information determined by the processors, information obtained from servers, information obtained from client devices, or other information that enables the functionality as described herein.

In some embodiments, system 300 and/or one or more models herein may be implemented using an application-specific integrated circuit. An integrated circuit may be a small electronic device made of semiconductor material, typically silicon, that contains a large number of microscopic electronic components such as transistors, resistors, capacitors, and diodes. These components are interconnected to perform a specific function or set of functions. Integrated circuits can be classified into various types based on their functionality, such as analog, digital, and mixed-signal ICs. The transistors within an IC are the primary building blocks, as they act as switches or amplifiers for electronic signals. The other components, like resistors and capacitors, are used for controlling voltage, current, and timing within the circuit. System 300 may design the integrated circuit to be application-specific such that design of the circuit is customized for a given application. In some embodiments, system 300 may use an integrated circuit system where one or more integrated circuits are spread throughout a system, network, and/or one or more devices. In such a case, the system design may ensure that the circuits are integrated with other electronic components like connectors, power supplies, and sensors to form a complete and functional electronic system. This integration allows for the implementation of sophisticated tasks in devices needed for one or more specified applications.

FIG. 3 also includes communication paths 328, 330, and 332. Communication paths 328, 330, and 332 may include the Internet, a mobile phone network, a mobile voice or data network (e.g., a 5G or LTE network), a cable network, a public switched telephone network, or other types of communications networks or combinations of communications networks. Communication paths 328, 330, and 332 may separately or together include one or more communications paths, such as a satellite path, a fiber-optic path, a cable path, a path that supports Internet communications (e.g., IPTV), free-space connections (e.g., for broadcast or other wireless signals), or any other suitable wired or wireless communications path or combination of such paths. The computing devices may include additional communication paths linking a plurality of hardware, software, and/or firmware components operating together. For example, the computing devices may be implemented by a cloud of computing platforms operating together as the computing devices.

Cloud components 310 may include model 302, which may be a machine learning model, artificial intelligence model, etc. (which may be referred to collectively as “models” herein). In recent years, the use of artificial intelligence, including, but not limited to, machine learning, deep learning, etc. (referred to collectively herein as artificial intelligence models, machine learning models, or simply models) has exponentially increased. Broadly described, artificial intelligence refers to a wide-ranging branch of computer science concerned with building smart machines capable of performing tasks that typically require human intelligence. Key benefits of artificial intelligence are its ability to process data, find underlying patterns, and/or perform real-time determinations. However, despite these benefits and despite the wide-ranging number of potential applications, practical implementations of artificial intelligence have been hindered by several technical problems. First, artificial intelligence may rely on large amounts of high-quality data. The process for obtaining this data and ensuring it is high-quality can be complex and time-consuming. Additionally, data that is obtained may need to be categorized and labeled accurately, which can be difficult, time-consuming and a manual task. Second, despite the mainstream popularity of artificial intelligence, practical implementations of artificial intelligence may require specialized knowledge to design, program, and integrate artificial intelligence-based solutions, which can limit the number of people and resources available to create these practical implementations. Finally, results based on artificial intelligence can be difficult to review as the process by which the results are made may be unknown or obscured. This obscurity can create hurdles for identifying errors in the results, as well as improving the models providing the results.

Model 302 may take inputs 304 and provide outputs 306. The inputs may include multiple datasets, such as a training dataset and a test dataset. Each of the plurality of datasets (e.g., inputs 304) may include data subsets related to user data, predicted forecasts and/or errors, and/or actual forecasts and/or errors. In some embodiments, outputs 306 may be fed back to model 302 as input to train model 302 (e.g., alone or in conjunction with user indications of the accuracy of outputs 306, labels associated with the inputs, or with other reference feedback information). For example, the system may receive a first labeled feature input, wherein the first labeled feature input is labeled with a known prediction for the first labeled feature input. The system may then train the first machine learning model to classify the first labeled feature input with the known prediction (e.g., a parameter weight, a merged model, etc.).

In a variety of embodiments, model 302 may update its configurations (e.g., weights, biases, or other parameters) based on the assessment of its prediction (e.g., outputs 306) and reference feedback information (e.g., user indication of accuracy, reference labels, or other information). In a variety of embodiments, where model 302 is a neural network, connection weights may be adjusted to reconcile differences between the neural network's prediction and reference feedback. In a further use case, one or more neurons (or nodes) of the neural network may require that their respective errors are sent backward through the neural network to facilitate the update process (e.g., backpropagation of error). Updates to the connection weights may, for example, be reflective of the magnitude of error propagated backward after a forward pass has been completed. In this way, for example, the model 302 may be trained to generate better predictions.

In some embodiments, model 302 may include an artificial neural network such as a large language model. In such embodiments, model 302 may include an input layer and one or more hidden layers. Each neural unit of model 302 may be connected with many other neural units of model 302. Such connections can be enforcing or inhibitory in their effect on the activation state of connected neural units. In some embodiments, each individual neural unit may have a summation function that combines the values of all of its inputs. In some embodiments, each connection (or the neural unit itself) may have a threshold function such that the signal must surpass it before it propagates to other neural units. Model 302 may be self-learning and trained, rather than explicitly programmed, and can perform significantly better in certain areas of problem-solving, as compared to traditional computer programs. During training, an output layer of model 302 may correspond to a classification of model 302, and an input known to correspond to that classification may be input into an input layer of model 302 during training. During testing, an input without a known classification may be input into the input layer, and a determined classification may be output.

In some embodiments, model 302 may include multiple layers (e.g., where a signal path traverses from front layers to back layers). In some embodiments, backpropagation techniques may be utilized by model 302, where forward stimulation is used to reset weights on the “front” neural units. In some embodiments, stimulation and inhibition for model 302 may be more free-flowing, with connections interacting in a more chaotic and complex fashion. During testing, an output layer of model 302 may indicate whether or not a given input corresponds to a classification of model 302 (e.g., a parameter weight, a merged model, etc.).

In some embodiments, the model (e.g., model 302) may automatically perform actions based on outputs 306. In some embodiments, the model (e.g., model 302) may not perform any actions. The output of the model (e.g., model 302) may be used to determine a parameter weight, a merged model, etc.

In some embodiments, the system may generate predictions related to financial services. For example, the system may use one or more models and/or applications to process a variety of data to generate predictions for tasks such as payment card eligibility determinations, fraud detection, and/or determining rates for auto-finance applications. For credit card eligibility, the model may use data such as the applicant's credit score, income, employment history, debt-to-income ratio, and past credit history. This data helps the model predict the likelihood of the applicant repaying the credit card debt. For fraud detection, models analyze transaction data, including the amount, location, frequency, and pattern of transactions. They compare these patterns to known fraudulent behavior to identify potentially fraudulent activities. For determining auto-finance rates, models might use the applicant's credit score, loan amount, loan term, vehicle details, and market interest rates. The data used by these models comes from various sources, including credit bureaus, financial institutions, customer-provided information, transaction records, and public records. By analyzing these data points, models can make informed predictions and decisions that help financial institutions manage risk, provide appropriate services, and enhance customer satisfaction.

In some embodiments, the model may process received data through several stages. For example, the model may collect and aggregate data from various sources (e.g., a user account, industry data, third-party data sources, etc.). The system may ensure the data is cleaned and preprocessed to handle any missing and/or inconsistent information. This preprocessing may include normalizing numerical data, encoding categorical variables, and applying techniques to handle outliers. The model may then use feature engineering to identify and create relevant features that can improve its predictive power. For instance, the system may derive new variables from existing ones, such as calculating the debt-to-income ratio from debt and income data.

Once the data is prepared, the system feeds the data into the model, which could be an artificial intelligence algorithm such as logistic regression, decision trees, and/or neural networks. The model may be trained on historical data, learning patterns, and/or relationships between input features and the target outcomes. During this training process, the system may adjust the model parameters to minimize prediction errors. After training, the system may validate the model and test the model using separate data sets to ensure the model has a predetermined and/or threshold accuracy and generalizability.

In some embodiments, the system may use specialized predictions based on the task. Additionally or alternatively, the system may adjust the inputs and/or outputs based on the determinations and/or predictions required. For example, for credit card eligibility, the model may evaluate the applicant's likelihood of defaulting on payments. In fraud detection, the model may identify anomalies and patterns indicative of fraudulent behavior. In auto-finance rate determination, the model may predict the risk associated with lending to an individual and adjust the interest rates accordingly. In some embodiments, the entire process may be iterative, with models continually updated and refined as new data becomes available, ensuring they remain effective in making accurate and reliable predictions.

System 300 also includes API layer 350. API layer 350 may allow the system to generate summaries across different devices. In some embodiments, API layer 350 may be implemented on mobile device 322 or user terminal 324. Alternatively or additionally, API layer 350 may reside on one or more of cloud components 310. API layer 350 (which may be a REST or Web services API layer) may provide a decoupled interface to data and/or functionality of one or more applications. API layer 350 may provide a common, language-agnostic way of interacting with an application. Web services APIs offer a well-defined contract, called WSDL, that describes the services in terms of their operations and the data types used to exchange information. REST APIs do not typically have this contract; instead, they are documented with client libraries for most common languages, including Ruby, Java, PHP, and JavaScript. SOAP Web services have traditionally been adopted in the enterprise for publishing internal services, as well as for exchanging information with partners in B2B transactions.

API layer 350 may use various architectural arrangements. For example, system 300 may be partially based on API layer 350, such that there is strong adoption of SOAP and RESTful Web services, using resources like Service Repository and Developer Portal, but with low governance, standardization, and separation of concerns. Alternatively, system 300 may be fully based on API layer 350, such that separation of concerns between layers like API layer 350, services, and applications are in place.

In some embodiments, the system architecture may use a microservice approach. Such systems may use two types of layers: Front-End Layer and Back-End Layer where microservices reside. In this kind of architecture, the role of the API layer 350 may provide integration between Front-End and Back-End. In such cases, API layer 350 may use RESTful APIs (exposition to front-end or even communication between microservices). API layer 350 may use AMQP (e.g., Kafka, RabbitMQ, etc.). API layer 350 may use incipient usage of new communications protocols such as gRPC, Thrift, etc.

In some embodiments, the system architecture may use an open API approach. In such cases, API layer 350 may use commercial or open source API Platforms and their modules. API layer 350 may use a developer portal. API layer 350 may use strong security constraints applying WAF and DDoS protection, and API layer 350 may use RESTful APIs as standard for external integration.

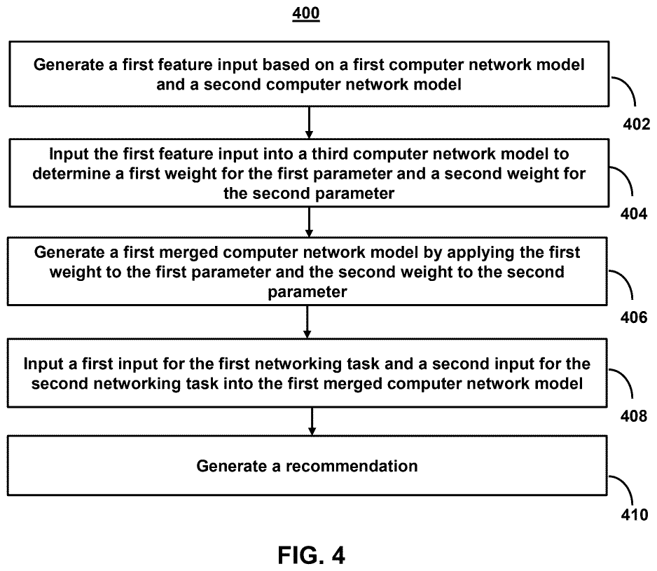

FIG. 4 shows a flowchart of the steps involved in merging computer network models, in accordance with one or more embodiments. For example, the system may use process 400 (e.g., as implemented on one or more system components described above) in order to merge computer network models based on parameter-specific node weights.

In some embodiments, the system may receive a user request to perform the first networking task and the second networking task and select the first merged computer network model from a plurality of merged computer network models based on the user request. For example, the system may receive a user request to perform both a first networking task and a second networking task through a user interface, such as a command-line input, graphical control panel, or API call that specifies the desired operations. The request may explicitly mention the tasks—such as “optimize routing” for the first task and “monitor traffic anomalies” for the second—or it may imply them through contextual language or parameter specifications. Upon receiving the request, the system parses the input to identify the required tasks and matches them to known task definitions stored in its internal registry. It then accesses a repository of pre-generated merged computer network models, each calibrated for various combinations of tasks and performance profiles. Using a model selection function, the system evaluates which of the available merged models best aligns with the combination of tasks specified in the request. This evaluation may involve checking metadata associated with each model—such as the specific tasks it supports, its performance scores on validation datasets, or its compatibility with current system constraints. Once the optimal model is identified—i.e., a model that incorporates the capabilities of both the first and second networking tasks—the system selects it for deployment. This approach allows the system to dynamically match user needs to a suitable, pre-merged model, thereby avoiding the need for real-time retraining while ensuring task-specific performance and efficiency.

At step 402, process 400 (e.g., using one or more components described above) generate a first feature input based on a first computer network model and a second computer network model. For example, the system may generate a first feature input based on a first computer network model and a second computer network model, wherein the first computer network model is calibrated for a first networking task and comprises a first parameter, and wherein the second computer network model is calibrated for a second networking task and comprises a second parameter. The system may generate a first feature input by leveraging the internal representations and parameters of both a first and a second computer network model, each calibrated for distinct networking tasks. The first computer network model is specifically tuned for a first task—such as packet routing optimization—and includes a first parameter that encapsulates learned behaviors or performance patterns related to that task. Similarly, the second computer network model is calibrated for a second task—such as traffic anomaly detection—and includes a second parameter reflecting its task-specific knowledge. To generate the first feature input, the system extracts relevant outputs, intermediate activations, or learned parameter values from both models. These extracted elements may include weights, embeddings, attention scores, or other quantifiable characteristics that represent how each model interprets or processes network-related data. The system then encodes or transforms this information into a unified feature input vector that synthesizes the critical aspects of both tasks. This feature input serves as a condensed representation of the combined operational context and is used for downstream tasks such as model merging, decision-making, or optimization. By integrating features derived from both models, the system ensures that the merged or subsequent operation is informed by the capabilities and insights of each specialized model, enabling more robust, multi-functional performance.

In some embodiments, the system may calibrate the first computer network model by receiving a first data sample corresponding to the first networking task and determining a first expected output corresponding to the first data sample. For example, the system may calibrate the first computer network model by initiating a task-specific training or fine-tuning process that aligns the model's behavior with the requirements of the first networking task. To begin, the system receives a first data sample relevant to that task—such as a packet flow pattern, routing table entry, or network topology snapshot—along with contextual metadata, if applicable. This data sample serves as an input for the model, which processes it using its current set of parameters to generate an initial output. In parallel, the system determines a first expected output corresponding to the same data sample. This expected output represents the correct or desired outcome for the first networking task and may be provided through a labeled training dataset, expert annotations, or simulated ground truth. The system then compares the model's output with the expected output using a predefined loss or error function, such as cross-entropy for classification or mean squared error for regression. Based on this comparison, the system adjusts the model's internal parameters—through techniques like backpropagation and gradient descent—to minimize the discrepancy between predicted and expected results. This iterative process continues across many data samples until the model demonstrates satisfactory performance on the task. Through this calibration, the system ensures that the first computer network model accurately interprets and responds to inputs associated with the first networking task.

In some embodiments, the system may generate the first feature input by determining a first node-mapping for the first computer network model, determining a first node based on the first node-mapping, and determining the first parameter corresponding to the first node. For example, the system may generate the first feature input by first determining a first node-mapping for the first computer network model, which defines the internal structure and relationships among computational nodes—such as layers, units, or processing elements—within the model. This node-mapping serves as a blueprint that outlines how data flows through the model and where key computations occur. From this mapping, the system identifies a first node that plays a critical role in performing the model's designated function for the first networking task. The selection of this node may be based on its position within the model architecture, its influence on the output, or its relevance to task-specific operations. Once the node is identified, the system locates the first parameter associated with that node—such as a weight, bias, or activation value—which has been learned or fine-tuned during the model's calibration process. This parameter reflects the knowledge embedded in that part of the model and is representative of how the model processes input features. The system then incorporates this parameter into a broader feature input vector, either directly or through a transformation (e.g., normalization, embedding), to capture the functional characteristics of the first model. This feature input can be used for downstream tasks such as model merging, performance evaluation, or adaptive control. By targeting specific nodes and their corresponding parameters, the system ensures that the generated feature input accurately reflects meaningful, task-relevant behavior within the model.

In some embodiments, the system may calibrate the first computer network model by receiving a user request to perform the first networking task and the second networking task and determining to generate the first merged computer network model based on the first computer network model and the second computer network model based on the user request. For example, the system may calibrate the first computer network model in response to a user request that specifies the need to perform both a first networking task and a second networking task. Upon receiving this request—via an interface such as a user dashboard, command line, or programmatic API—the system interprets the intended objectives and identifies the models associated with each task. Recognizing that the first computer network model is calibrated for the first task and the second model is calibrated for the second task, the system determines that fulfilling the combined request requires the creation of a merged model that integrates both capabilities. Instead of recalibrating the first model in isolation, the system opts to generate a first merged computer network model that leverages the learned parameters and node structures from both source models. This merged model is constructed to accommodate the requirements of both tasks simultaneously, ensuring that the functionality of the first model is preserved while being extended to incorporate the operational logic of the second model. The calibration process thus becomes a higher-level adaptation step, in which the system refines the alignment of models to user intent by intelligently selecting and merging appropriate components, rather than retraining a single model from scratch. This approach allows the system to efficiently respond to multi-task demands while maintaining accuracy and minimizing redundant computation.

At step 404, process 400 (e.g., using one or more components described above) input the first feature input into a third computer network model to determine a first weight for the first parameter and a second weight for the second parameter. For example, the system may input the first feature input into a third computer network model to determine a first weight for the first parameter and a second weight for the second parameter, wherein the third computer network model is trained to determine consolidated models by merging inputted computer network models by modifying weights attributed to individual parameters. The system may input the first feature input into a third computer network model that is specifically trained to facilitate the merging of other computer network models by learning how to assign optimal weights to their individual parameters. The first feature input, generated from the first and second models, encapsulates critical information such as task relevance, parameter influence, node mappings, or performance characteristics of the source models. Once this feature input is provided to the third model, it processes the data using its own learned internal representations to evaluate the relative importance of the parameters from each source model. The third model, having been trained on examples of effective model combinations, outputs a first weight corresponding to the first parameter from the first computer network model and a second weight corresponding to the second parameter from the second computer network model. These weights reflect the learned contributions of each parameter toward achieving optimal performance in a merged context. By assigning these weights, the third model guides the merging process, enabling the system to consolidate the two source models into a unified model that balances their strengths. This method allows for automated, data-driven parameter merging and supports flexible adaptation across diverse tasks or domains without requiring manual tuning or retraining.

In some embodiments, the system may input the first feature input into the third computer network model to determine the first weight for the first parameter and the second weight for the second parameter by determining a first hyperparameter of the first computer network model, determining a second hyperparameter of the second computer network model, and determining the first weight for the first parameter and the second weight for the second parameter without modifying the first hyperparameter of the second hyperparameter. The system may input the first feature input into a third computer network model to determine the first weight for the first parameter and the second weight for the second parameter by incorporating additional contextual information in the form of hyperparameters from the source models, without modifying those hyperparameters. Specifically, the system begins by identifying and retrieving a first hyperparameter from the first computer network model—such as learning rate, dropout rate, or number of layers—which governs the behavior and training dynamics of that model. Similarly, it retrieves a second hyperparameter from the second computer network model. These hyperparameters provide structural and optimization context that can influence how each model's parameters should contribute to a merged solution. The system then combines the first feature input (which encapsulates node-specific parameter information and task-relevant details) with this hyperparameter metadata to form a comprehensive input to the third computer network model. The third model processes this enriched input to evaluate the significance of the first and second parameters within the broader task context, ultimately producing a first weight for the first parameter and a second weight for the second parameter. Importantly, during this process, the original hyperparameters from the first and second models remain unchanged—they are used purely as static reference information to inform the weighting decision, not as modifiable variables. This ensures that the merging logic remains agnostic to the training configurations of the source models while still leveraging their structural characteristics to guide a more intelligent and task-aligned parameter consolidation.

In some embodiments, the system may input the first feature input into the third computer network model to determine the first weight for the first parameter and the second weight for the second parameter by retrieving the first computer network model and the second computer network model and determining the first weight for the first parameter and the second weight for the second parameter without retraining the first computer network model and the second computer network model. For example, the system may input the first feature input into a third computer network model to determine the first weight for the first parameter and the second weight for the second parameter by leveraging a non-retraining, parameter-merging strategy. Initially, the system retrieves the first computer network model and the second computer network model, each of which has already been trained independently for their respective tasks and contains fixed, optimized parameter sets. Without modifying or retraining these models, the system generates a first feature input that captures relevant information about the models' internal structure, task alignment, parameter characteristics, and performance context. This feature input is then supplied to the third computer network model, which has been pre-trained to understand how to merge models effectively by assigning weights to individual parameters. Using the information encoded in the feature input, the third model evaluates the contributions of the first parameter from the first model and the second parameter from the second model. It then outputs a first weight and a second weight, each corresponding to the relative importance of the parameters in the merged model configuration. Throughout this process, the original first and second models remain unchanged—their parameters and hyperparameters are preserved as-is. This approach enables the system to dynamically merge models based on their learned representations and contextual value, while avoiding the computational cost and complexity of retraining the source models. It supports rapid, flexible model composition for multi-task or domain-adaptive applications.

At step 406, process 400 (e.g., using one or more components described above) generate a first merged computer network model by applying the first weight to the first parameter and the second weight to the second parameter. For example, the system may generate a first merged computer network model by applying the first weight to the first parameter and the second weight to the second parameter when processing inputs through the first computer network model and the second computer network model, respectively. For example, the system may generate a first merged computer network model by applying the first weight to the first parameter and the second weight to the second parameter during the integration of the first and second computer network models. After determining the optimal weights—based on input from a third model or a task-specific merging strategy—the system does not retrain or modify the source models but instead combines them by weighting their parameters directly during model composition. Specifically, the system processes the corresponding nodes and layers of the first and second models and, for each parameter pair (e.g., weights or biases associated with similar functions or positions in the network architecture), multiplies the parameter from the first model by the first weight and the parameter from the second model by the second weight. These weighted parameters are then aggregated—typically by summing or averaging—to form a single, consolidated parameter that is used in the merged model. This operation is repeated across the aligned layers or parameter sets of both models, resulting in a unified parameter set for the merged model. When the merged model processes new input data, it does so using this combined set of weighted parameters, effectively leveraging the learned capabilities of both source models. This approach enables the merged model to inherit the task-specific strengths of each individual model while operating as a coherent, single network, all without requiring retraining of the original models.

In some embodiments, the system may generate the first merged computer network model by determining a first dimension for the first computer network model and a second dimension for the second computer network model and adjusting the first dimension and the second dimension. For example, the system may generate the first merged computer network model by first determining the architectural dimensions of the source models—specifically, a first dimension for the first computer network model and a second dimension for the second computer network model. These dimensions may refer to the shape or size of key model components such as layer widths, input/output tensor dimensions, embedding sizes, or feature map resolutions, which must be compatible for parameter-level operations like merging. Once the system identifies these dimensions, it evaluates whether they are aligned or require transformation to enable a coherent merging process. If the dimensions differ, the system applies adjustment techniques such as dimensional projection, padding, interpolation, or linear transformations to reconcile the differences. For instance, it may reduce or expand the size of a layer's output or map higher-dimensional parameters into a common latent space. These adjustments ensure that parameters from both models can be combined without loss of structural integrity or semantic meaning. After alignment, the system proceeds to merge the parameters—often by applying weighting or averaging strategies—resulting in a first merged computer network model that integrates the capabilities of both original models while maintaining architectural consistency. This process allows for flexible model composition across structurally diverse networks, enabling broader applicability in multi-task or cross-domain environments.

At step 408, process 400 (e.g., using one or more components described above) input a first input for the first networking task and a second input for the second networking task into the first merged computer network model. For example, the system may input a first input for the first networking task and a second input for the second networking task into the first merged computer network model to generate a first output for the first networking task and a second output for the second networking task. The system may input a first input for the first networking task and a second input for the second networking task into the first merged computer network model by leveraging the model's integrated architecture, which is designed to handle multiple task-specific inputs simultaneously or sequentially. Upon receiving the first input—such as routing data, packet flow information, or network topology details relevant to the first networking task—the system feeds this data into the merged model, which internally routes it through the parameter pathways that originated from the first computer network model. Concurrently or subsequently, the second input—such as traffic logs or anomaly indicators for the second networking task—is processed by the merged model using the parameter regions derived from the second computer network model. Because the merged model is constructed using a blend of parameters from both source models, with weighted contributions preserving task-specific functionality, it can generate distinct outputs for each task. The model produces a first output tailored to the objectives of the first networking task and a second output optimized for the second task. This output generation may occur in parallel or be scheduled through a task-specific inference module, depending on the merged model's design. Ultimately, the merged model acts as a unified inference engine capable of executing both tasks with task-aligned precision, without requiring separate processing pipelines or model switching.

In some embodiments, the system may generate the first merged computer network model by determining a first number of layers for the first computer network model and a second number of layers for the second computer network model and adjusting the first number of layers and the second number of layers. For example, the system may generate the first merged computer network model by initially determining the architectural depth of each source model, specifically identifying the first number of layers in the first computer network model and the second number of layers in the second computer network model. These layers represent the sequence of computational operations—such as convolutions, fully connected layers, or attention blocks—that process input data and learn task-specific features. If the two models have different numbers of layers, the system must reconcile these structural differences before merging. To do this, it may adjust the number of layers in one or both models through techniques such as layer alignment, truncation, duplication, or intermediate mapping. For instance, the system may remove excess layers from the deeper model, interpolate hidden states across mismatched layers, or insert adapter layers to bridge architectural gaps. These adjustments ensure that corresponding layers between the two models are compatible and can be effectively merged, either by averaging their parameters, applying weighted combinations, or stacking them in a hybrid configuration. Once the layer structures are aligned, the system proceeds to blend the parameters to form a unified, task-preference-calibrated architecture. This process enables the creation of a merged computer network model that integrates the functional depth of both source models while maintaining operational coherence and compatibility for downstream tasks.

In some embodiments, the system may generate the first merged computer network model by determining a first sparsity for the first computer network model and a second sparsity for the second computer network model and adjusting the first sparsity and the second sparsity. For example, the system may generate the first merged computer network model by first determining the first sparsity of the first computer network model and the second sparsity of the second computer network model. Sparsity refers to the proportion of parameters in a model that are zero or inactive, often introduced deliberately to reduce computational complexity, memory usage, or overfitting. Each model may exhibit different sparsity levels depending on how they were trained or pruned for their respective tasks. To merge these models effectively, the system must reconcile these differences in sparsity to ensure consistency and functional integrity in the resulting architecture. This may involve adjusting the sparsity levels by reactivating certain pruned parameters, pruning additional weights, or applying sparse-to-dense transformations so that corresponding parameters across both models can be meaningfully aligned. In some cases, the system may compute an intermediate sparsity level for merged parameters or apply task-weighted sparsity regularization to balance model efficiency with performance across both domains. Once the sparsity levels are harmonized, the system combines the parameters—typically through weighted averaging or optimization-based merging strategies—to form the first merged computer network model. This model benefits from the efficiency gains of sparsity while maintaining the task-specific expressiveness of both original models, enabling a compact and capable architecture for multi-task or domain-adaptive deployment.

In some embodiments, the system may generate the first merged computer network model by determining, using a mapping function, a first parameter contribution of the first computer network model, determining, using the mapping function, a second parameter contribution of the second computer network model, and determining the first merged computer network model based on the first parameter contribution and the second parameter contribution. For example, the system may generate the first merged computer network model by using a mapping function to quantify and guide how parameters from the source models contribute to the final merged architecture. First, the system applies the mapping function to the first computer network model to determine the first parameter contribution, which represents the relative importance or influence of the model's parameters—such as weights, biases, or node activations—in accomplishing its designated networking task. This contribution may be computed by analyzing performance metrics, sensitivity of outputs to specific parameters, or their structural alignment within the model. The same mapping function is then applied to the second computer network model to determine the second parameter contribution using similar evaluation criteria, tailored to the second task. Once both contributions are assessed, the system uses these values to guide how parameters from each model are combined to form the first merged computer network model. For instance, if certain parameters from the first model show higher contribution to task performance, they may be assigned greater weight in the merging process, while lower-contributing parameters from the second model may be downweighted or omitted. This contribution-aware merging ensures that the most impactful features from both models are preserved and appropriately balanced, resulting in a unified model that integrates the strengths of both sources while remaining efficient and task-aligned. The mapping function thus serves as a central mechanism for prioritizing, scaling, and integrating parameters during the model consolidation process.

In some embodiments, the system may generate the first merged computer network model by retrieving a first Gaussian optimization function and determining the first merged computer network model based on the first Gaussian optimization function. For example, the system may generate the first merged computer network model by retrieving a first Gaussian optimization function and using it to intelligently search for an optimal combination of parameters from two or more source models. Gaussian optimization, a gradient-free optimization technique, is particularly useful for exploring high-dimensional parameter spaces efficiently when the objective function is expensive to evaluate or lacks analytical gradients. Upon retrieving this function, the system defines an objective—such as maximizing task performance or minimizing prediction error on a validation dataset—and then uses the Gaussian optimization function to iteratively sample weight configurations that blend parameters from the first and second computer network models. For each sampled configuration, the system temporarily constructs a candidate merged model by applying the sampled weights to the corresponding parameters of the original models, evaluates the model's performance on the target task, and updates a probabilistic model of the performance landscape (typically a Gaussian process). This surrogate model is used to identify promising regions in the parameter space and guide the next round of sampling. Through successive iterations, the system converges on a high-performing parameter combination, which is then used to define the final merged computer network model. By leveraging Gaussian optimization, the system avoids retraining and instead relies on data-efficient exploration to produce a merged model that captures the strengths of its component models while being optimized for the intended application.

In some embodiments, the system may generate the first merged computer network model by using a Bayesian optimization to construct a posterior distribution of functions and determining the first merged computer network model based on the posterior distribution of functions. For example, the system may generate the first merged computer network model by using Bayesian optimization to construct a posterior distribution of functions that models the performance of different combinations of parameters from source models. Bayesian optimization is a powerful technique for optimizing black-box functions where evaluations are costly and gradients are unavailable. In this context, the system first defines an objective function—such as task-specific model accuracy, loss minimization, or output alignment—based on how well a merged model performs when using specific parameter weightings from the first and second computer network models. The system starts with a prior distribution over possible parameter combination functions, which represents its initial beliefs about which parameter weightings might yield the best performance. As the system samples different combinations and evaluates their performance, it updates this belief using Bayes' theorem, forming a posterior distribution that reflects both the prior and the evidence from sampled evaluations.

This posterior distribution allows the system to predict which parameter combinations are most likely to result in high-performing merged models. Using an acquisition function—such as expected improvement or upper confidence bound—the system selects the most promising next combinations to evaluate. This cycle continues iteratively, efficiently narrowing the search space and focusing on areas with high expected performance. Ultimately, the system uses the best-performing parameter configuration, as indicated by the posterior distribution, to define the final first merged computer network model. This model blends the most relevant contributions from the first and second source models and is optimized based on empirical evidence gathered during the Bayesian optimization process. This approach ensures that the merged model is both data-driven and statistically grounded, delivering high performance without exhaustive trial-and-error or retraining.

In some embodiments, the system may generate the first merged computer network model by receiving a first node-mapping for the first computer network model, receiving a second node-mapping for the second computer network model, and generating a first consolidated node-mapping for the first merged computer network model based on the first node-mapping and the second node-mapping. For example, the system may generate the first merged computer network model by first receiving a first node-mapping for the first computer network model and a second node-mapping for the second computer network model. Each node-mapping defines the structural layout and interconnections of computational nodes—such as layers, neurons, or processing units—within its respective model. These mappings include information about the roles of individual nodes, the data flow paths between them, and the parameters associated with each node. Upon receiving both mappings, the system analyzes their structural similarities and differences to identify corresponding or functionally related nodes across the two models. It then constructs a first consolidated node-mapping for the merged model by aligning or integrating these matched nodes and their associated parameters. This may involve techniques such as averaging parameters of matched nodes, creating hybrid nodes that inherit behavior from both models, or inserting intermediate layers or connectors to reconcile architectural differences. The consolidated node-mapping preserves task-relevant pathways from both source models, ensuring that the merged model maintains the functional integrity and performance characteristics needed to handle multiple tasks or domains. This node-level integration strategy allows the system to produce a coherent, merged network architecture that combines the structural and functional strengths of the original models in a unified framework.

At step 410, process 400 (e.g., using one or more components described above) generate a recommendation. For example, the system may generate for display, in a user interface, a recommendation based on the first output and the second output. The system may generate for display, in a user interface, a recommendation based on the first output and the second output by first analyzing the outputs generated by the merged computer network model for the respective networking tasks. The first output may correspond to the result of the first networking task—such as routing optimization or bandwidth allocation—while the second output may relate to the second task, such as anomaly detection or network health monitoring. The system processes these outputs using a decision-making or recommendation module, which interprets the results in the context of predefined criteria, thresholds, or user preferences. It may also integrate auxiliary data, such as historical trends or real-time constraints, to refine the recommendation. Once a relevant insight or action is derived—such as “reroute traffic through Node A for improved efficiency” or “flag connection from IP X as a potential threat” the system formats this information into a user-friendly message or alert. This recommendation is then rendered through the user interface, using intuitive visuals, text, or interactive elements depending on the platform (e.g., dashboard, mobile app, or admin console). By contextualizing the model outputs into actionable, comprehensible guidance, the system enables users to make informed decisions and respond effectively to dynamic networking conditions.

It is contemplated that the steps or descriptions of FIG. 4 may be used with any other embodiment of this disclosure. In addition, the steps and descriptions described in relation to FIG. 4 may be done in alternative orders or in parallel to further the purposes of this disclosure. For example, each of these steps may be performed in any order, in parallel, or simultaneously to reduce lag or increase the speed of the system or method. Furthermore, it should be noted that any of the components, devices, or equipment discussed in relation to the figures above could be used to perform one or more of the steps in FIG. 4.

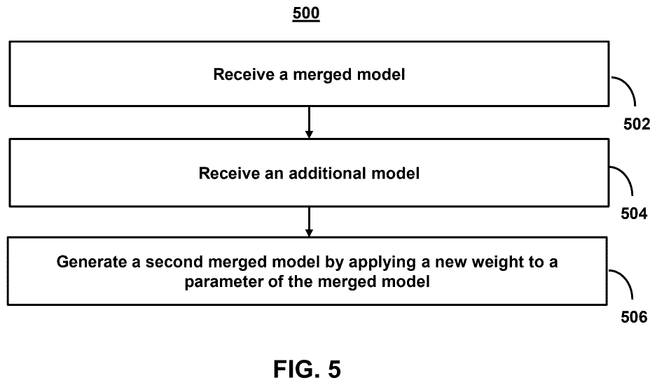

FIG. 5 shows a flowchart of the steps involved in merging another model to an existing merged model, in accordance with one or more embodiments. For example, the system may use process 500 (e.g., as implemented on one or more system components described above) in order to merge models based on parameter-specific node weights.

At step 502, process 500 (e.g., using one or more components described above) receives a merged model. For example, when the system receives a merged model, the process typically begins with the model being transferred from a storage or deployment pipeline, often as a serialized artifact such as a .pt, .bin, or .onnx file depending on the framework used (e.g., PyTorch, TensorFlow, ONNX). The merged model, which may combine parameters from multiple sources (such as fine-tuned components or ensemble strategies), is loaded into memory by the system's inference or training environment. This loading process involves deserializing the model and mapping its architecture to the appropriate runtime, such as a CPU or GPU execution context. Once loaded, the system may perform integrity checks to ensure compatibility between the merged components, validate the model's structure against expected schemas, and prepare associated resources like tokenizers, configuration files, and dependency layers. The system may then optimize the model for performance, such as converting it to a lower-precision format (e.g., FP16 or INT8) or compiling it with inference engines like TensorRT. Finally, the model becomes available for inference or further training, depending on the system's purpose, with all upstream components synchronized to utilize the updated model instance.

At step 504, process 500 (e.g., using one or more components described above) receives an additional model. For example, the system may receive an additional model for merging through various input channels, depending on its architecture and integration with external services. This process typically involves the new model being uploaded or transmitted to the system as a serialized file—commonly in formats such as .pt, .ckpt, or .bin—via an API call, a user interface, or through automated pipelines connected to a model registry or artifact storage. Upon receipt, the system first verifies the model's compatibility by checking its architecture, parameter dimensions, and training metadata against existing models. It then deserializes the new model and loads its weights into memory, either entirely or selectively, depending on the merging strategy—such as averaging parameters, layer-wise integration, or using adapters. If the models originate from different training regimes or objectives, the system may also normalize or align them using techniques like weight scaling or intermediate transformation layers to preserve performance integrity. Once validated and prepared, the system proceeds with the merge, either statically (resulting in a single unified model file) or dynamically (retaining the models separately but combining their outputs during inference). This modular process allows flexible model experimentation, enhancement, or ensemble construction.

At step 506, process 500 (e.g., using one or more components described above) generates a second merged model by applying a new weight to a parameter of the merged model. For example, the system may generate a second merged model by applying a new weight to a parameter of an existing merged model through a process involving selective parameter reweighting and reserialization. First, the system loads the initial merged model into memory, accessing its parameter tensors—such as weight matrices or bias vectors—typically using a deep learning framework like PyTorch or TensorFlow. It identifies the specific parameter or set of parameters to be adjusted, either by name (e.g., layer1.weight) or by their position in the model architecture. The system then applies the new weight as a scalar multiplier or as part of a more complex transformation, such as a linear combination with another tensor (e.g., new_param=alpha*original_param+beta*delta_param). This adjustment recalibrates the model's internal representations, potentially influencing its behavior during inference or training. After modifying the designated parameters, the system integrates the updated values back into the model structure and performs consistency checks to ensure the modifications do not violate architectural constraints. Finally, it serializes the updated model as a new artifact, preserving the original model for reproducibility and enabling deployment or further experimentation with the second, newly weighted merged model.

In some embodiments, the system may further iterate through model merging. For example, the system may generate a second feature input based on the first merged computer network model and a third computer network model, wherein the third computer network model is calibrated for a third networking task and comprises a third parameter, input the first feature input into the third computer network model to determine a third weight for the third parameter and new weights for the first parameter and the second parameter, and generate a second merged computer network model based on the third weight and the new weights. The system may generate a second feature input by analyzing the structure and parameters of the first merged computer network model alongside those of a third computer network model, which is calibrated for a distinct third networking task and contains a unique third parameter. To begin, the system extracts relevant features from the first merged model—such as parameter statistics, node mappings, and previously applied weights for the first and second parameters—and combines them with corresponding features from the third model, including its task calibration context and third parameter characteristics. These combined insights form the second feature input, which encapsulates the structural and functional relationships between all three models.

This second feature input is then supplied to a specialized model—such as a third computer network model trained for parameter merging or optimization—which processes the input to compute a new set of weight values. Specifically, it outputs a third weight corresponding to the third parameter and revised or new weights for the first and second parameters, reflecting how the contributions of the original models should be rebalanced in light of the third task. These weights are then applied to their respective parameters across all three models. Using this updated configuration, the system generates a second merged computer network model that consolidates the knowledge from the first, second, and third models into a single, unified framework. This model is optimized to support all three networking tasks and represents a deeper level of task generalization and parameter integration, achieved without retraining the original models. The process enables the system to scale efficiently across additional tasks while maintaining performance integrity through intelligent parameter fusion.

It is contemplated that the steps or descriptions of FIG. 5 may be used with any other embodiment of this disclosure. In addition, the steps and descriptions described in relation to FIG. 5 may be done in alternative orders or in parallel to further the purposes of this disclosure. For example, each of these steps may be performed in any order, in parallel, or simultaneously to reduce lag or increase the speed of the system or method. Furthermore, it should be noted that any of the components, devices, or equipment discussed in relation to the figures above could be used to perform one or more of the steps in FIG. 5.

The above-described embodiments of the present disclosure are presented for purposes of illustration and not of limitation, and the present disclosure is limited only by the claims that follow. Furthermore, it should be noted that the features and limitations described in any one embodiment may be applied to any embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

The present techniques will be better understood with reference to the following enumerated embodiments:
1. A method for merging computer network models based on parameter-specific node weights.
2. The method of any one of the preceding embodiments, further comprising: generating a first feature input based on a first computer network model and a second computer network model, wherein the first computer network model is calibrated for a first networking task and comprises a first parameter, and wherein the second computer network model is calibrated for a second networking task and comprises a second parameter; inputting the first feature input into a third computer network model to determine a first weight for the first parameter and a second weight for the second parameter, wherein the third computer network model is trained to determine consolidated models by merging inputted computer network models by modifying weights attributed to individual parameters; generating a first merged computer network model by applying the first weight to the first parameter and the second weight to the second parameter when processing inputs through the first computer network model and the second computer network model, respectively; inputting a first input for the first networking task and a second input for the second networking task into the first merged computer network model to generate a first output for the first networking task and a second output for the second networking task; and generating for display, in a user interface, a recommendation based on the first output and the second output.
3. The method of any one of the preceding embodiments, wherein generating the first merged computer network model further comprises: determining a first dimension for the first computer network model and a second dimension for the second computer network model; and adjusting the first dimension and the second dimension.
4. The method of any one of the preceding embodiments, wherein generating the first merged computer network model further comprises: determining a first number of layers for the first computer network model and a second number of layers for the second computer network model; and adjusting the first number of layers and the second number of layers.
5. The method of any one of the preceding embodiments, wherein generating the first merged computer network model further comprises: determining a first sparsity for the first computer network model and a second sparsity for the second computer network model; and adjusting the first sparsity and the second sparsity.
6. The method of any one of the preceding embodiments, wherein generating the first merged computer network model further comprises: determining, using a mapping function, a first parameter contribution of the first computer network model; determining, using the mapping function, a second parameter contribution of the second computer network model; and determining the first merged computer network model based on the first parameter contribution and the second parameter contribution.
7. The method of any one of the preceding embodiments, wherein the first computer network model is calibrated for the first networking task by: receiving a first data sample corresponding to the first networking task; and determining a first expected output corresponding to the first data sample.
8. The method of any one of the preceding embodiments, wherein generating the first merged computer network model further comprises: retrieving a first Gaussian optimization function; and determining the first merged computer network model based on the first Gaussian optimization function.
9. The method of any one of the preceding embodiments, wherein generating the first merged computer network model further comprises: using a Bayesian optimization to construct a posterior distribution of functions; and determining the first merged computer network model based on the posterior distribution of functions.
10. The method of any one of the preceding embodiments, wherein inputting the first feature input into the third computer network model to determine the first weight for the first parameter and the second weight for the second parameter further comprises: determining a first hyperparameter of the first computer network model; determining a second hyperparameter of the second computer network model; and determining the first weight for the first parameter and the second weight for the second parameter without modifying the first hyperparameter of the second hyperparameter.
11. The method of any one of the preceding embodiments, wherein inputting the first feature input into the third computer network model to determine the first weight for the first parameter and the second weight for the second parameter further comprises: retrieving the first computer network model and the second computer network model; and determining the first weight for the first parameter and the second weight for the second parameter without retraining the first computer network model and the second computer network model.
12. The method of any one of the preceding embodiments, wherein generating the first merged computer network model further comprises: receiving a first node-mapping for the first computer network model; receiving a second node-mapping for the second computer network model; and generating a first consolidated node-mapping for the first merged computer network model based on the first node-mapping and the second node-mapping.
13. The method of any one of the preceding embodiments, wherein generating the first feature input further comprises: determining a first node-mapping for the first computer network model; determining a first node based on the first node-mapping; and determining the first parameter corresponding to the first node.
14. The method of any one of the preceding embodiments, wherein generating the first feature input further comprises: receiving a user request to perform the first networking task and the second networking task; and determining to generate the first merged computer network model based on the first computer network model and the second computer network model based on the user request.
15. The method of any one of the preceding embodiments, further comprising: generating a second feature input based on the first merged computer network model and a third computer network model, wherein the third computer network model is calibrated for a third networking task and comprises a third parameter; inputting the first feature input into the third computer network model to determine a third weight for the third parameter and new weights for the first parameter and the second parameter; and generating a second merged computer network model based on the third weight and the new weights.
16. The method of any one of the preceding embodiments, further comprises: receiving a user request to perform the first networking task and the second networking task; and selecting the first merged computer network model from a plurality of merged computer network models based on the user request.
17. One or more non-transitory, computer-readable mediums storing instructions that, when executed by a data processing apparatus, cause the data processing apparatus to perform operations comprising those of any of embodiments 1-16.
18. A system comprising one or more processors; and memory storing instructions that, when executed by the processors, cause the processors to effectuate operations comprising those of any of embodiments 1-16.
19. A system comprising means for performing any of embodiments 1-16.

What is claimed is:

1. One or more non-transitory, computer-readable media, comprising instructions that, when executed by one or more processors, cause operations comprising:
receiving a user request to perform a first networking task and a second networking task;
selecting a first merged computer network model from a plurality of merged computer network models based on the user request, wherein the first merged computer network model is generated by:
inputting a feature input based on a first computer network model and a second computer network model into a merging function to determine a first weight for a first parameter of the first computer network model corresponding to the first networking task and a second weight for a second parameter of a second computer network model corresponding to the second networking task, wherein the merging function modifies weights attributed to individual parameters; and
applying the first weight to the first parameter and the second weight to the second parameter when processing inputs through the first computer network model and the second computer network model, respectively;
inputting a first input for the first networking task and a second input for the second networking task into the first merged computer network model to generate a first output for the first networking task and a second output for the second networking task; and
generating for display, in a user interface, a recommendation based on the first output and the second output.

2. The one or more non-transitory, computer-readable media of claim 1, wherein generating the first merged computer network model further comprises:
determining, using a mapping function, a first parameter contribution of the first computer network model;
determining, using the mapping function, a second parameter contribution of the second computer network model; and
determining the first merged computer network model based on the first parameter contribution and the second parameter contribution.

3. The one or more non-transitory, computer-readable media of claim 2, wherein generating the first merged computer network model further comprises:
receiving a first node-mapping for the first computer network model;
receiving a second node-mapping for the second computer network model; and
generating a first consolidated node-mapping for the merged model based on the first node-mapping and the second node-mapping.

4. The one or more non-transitory, computer-readable media of claim 2, wherein generating the first merged computer network model further comprises:
determining a first node-mapping for the first computer network model;
determining a first node based on the first node-mapping; and
determining the first parameter corresponding to the first node.

5. A system for merging computer network models based on parameter-specific node weights, the system comprising:
one or more processors; and
one or more non-transitory, computer-readable media, comprising instructions that, when executed by the one or more processors, cause operations comprising:
receiving a first node-mapping for a first computer network model, wherein the first computer network model is calibrated for a first networking task, and wherein the first node-mapping comprises a first node with a first parameter;
receiving a second node-mapping for a second computer network model, wherein the second computer network model is calibrated for a second networking task, and wherein the second node-mapping comprises a second node with a second parameter;
generating a first feature input based on the first node-mapping and the second node-mapping;
inputting the first feature input into a third computer network model to determine a first weight for the first parameter and a second weight for the second parameter, wherein the third computer network model is trained to determine consolidated node-mappings by merging inputted node-mappings by modifying weights attributed to individual parameters;
generating a first consolidated node-mapping for a merged computer network model by applying the first weight to the first parameter and the second weight to the second parameter when processing inputs through the first computer network model and the second computer network model, respectively;
inputting a first input for the first networking task and a second input for the second networking task into the merged computer network model to generate a first output for the first networking task and a second output for the second networking task; and
generating for display, in a user interface, a recommendation based on the first output and the second output.

6. A method for merging computer network models based on parameter-specific node weights, the method comprising:
generating a first feature input based on a first computer network model and a second computer network model, wherein the first computer network model is calibrated for a first networking task and comprises a first parameter, and wherein the second computer network model is calibrated for a second networking task and comprises a second parameter;
inputting the first feature input into a third computer network model to determine a first weight for the first parameter and a second weight for the second parameter, wherein the third computer network model is trained to determine consolidated models by merging inputted computer network models by modifying weights attributed to individual parameters;
generating a first merged computer network model by applying the first weight to the first parameter and the second weight to the second parameter when processing inputs through the first computer network model and the second computer network model, respectively;
inputting a first input for the first networking task and a second input for the second networking task into the first merged computer network model to generate a first output for the first networking task and a second output for the second networking task; and
generating for display, in a user interface, a recommendation based on the first output and the second output.

7. The method of claim 6, wherein generating the first merged computer network model further comprises:
determining a first dimension for the first computer network model and a second dimension for the second computer network model; and
adjusting the first dimension and the second dimension.

8. The method of claim 6, wherein generating the first merged computer network model further comprises:
determining a first number of layers for the first computer network model and a second number of layers for the second computer network model; and
adjusting the first number of layers and the second number of layers.

9. The method of claim 6, wherein generating the first merged computer network model further comprises:
determining a first sparsity for the first computer network model and a second sparsity for the second computer network model; and
adjusting the first sparsity and the second sparsity.

10. The method of claim 6, wherein generating the first merged computer network model further comprises:
determining, using a mapping function, a first parameter contribution of the first computer network model;
determining, using the mapping function, a second parameter contribution of the second computer network model; and
determining the first merged computer network model based on the first parameter contribution and the second parameter contribution.

11. The method of claim 6, wherein the first computer network model is calibrated for the first networking task by:
receiving a first data sample corresponding to the first networking task; and
determining a first expected output corresponding to the first data sample.

12. The method of claim 6, wherein generating the first merged computer network model further comprises:
retrieving a first Gaussian optimization function; and
determining the first merged computer network model based on the first Gaussian optimization function.

13. The method of claim 6, wherein generating the first merged computer network model further comprises:
using a Bayesian optimization to construct a posterior distribution of functions; and
determining the first merged computer network model based on the posterior distribution of functions.

14. The method of claim 6, wherein inputting the first feature input into the third computer network model to determine the first weight for the first parameter and the second weight for the second parameter further comprises:
determining a first hyperparameter of the first computer network model;
determining a second hyperparameter of the second computer network model; and
determining the first weight for the first parameter and the second weight for the second parameter without modifying the first hyperparameter of the second hyperparameter.

15. The method of claim 6, wherein inputting the first feature input into the third computer network model to determine the first weight for the first parameter and the second weight for the second parameter further comprises:
retrieving the first computer network model and the second computer network model; and
determining the first weight for the first parameter and the second weight for the second parameter without retraining the first computer network model and the second computer network model.

16. The method of claim 6, wherein generating the first merged computer network model further comprises:
receiving a first node-mapping for the first computer network model;
receiving a second node-mapping for the second computer network model; and
generating a first consolidated node-mapping for the first merged computer network model based on the first node-mapping and the second node-mapping.

17. The method of claim 6, wherein generating the first feature input further comprises:
determining a first node-mapping for the first computer network model;
determining a first node based on the first node-mapping; and
determining the first parameter corresponding to the first node.

18. The method of claim 6, wherein generating the first feature input further comprises:
receiving a user request to perform the first networking task and the second networking task; and
determining to generate the first merged computer network model based on the first computer network model and the second computer network model based on the user request.

19. The method of claim 6, further comprising:
generating a second feature input based on the first merged computer network model and a third computer network model, wherein the third computer network model is calibrated for a third networking task and comprises a third parameter;
inputting the first feature input into the third computer network model to determine a third weight for the third parameter and new weights for the first parameter and the second parameter; and
generating a second merged computer network model based on the third weight and the new weights.

20. The method of claim 6, further comprises:
receiving a user request to perform the first networking task and the second networking task; and
selecting the first merged computer network model from a plurality of merged computer network models based on the user request.
